(19) United States
(12) Patent Application Publication
(10) Pub. No.: US 2007/0221978 A1
(43) Pub. Date: Sep. 27, 2007

(54) Semiconductor device

(75) Inventor: Kazuto Tsuji, Kawasaki-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/798,672

(22) Filed: May 16, 2007

Related U.S. Application Data
(63) Continuation of application No. PCT/JP04/17089, filed on Nov. 17, 2004.

(51) Int. Cl. H01L 29/94

(52) U.S. Cl. 257/306

(57) ABSTRACT

The semiconductor device comprises a substrate, a semiconductor element mounted on the substrate, a heat diffusion member mounted on the substrate while covering the semiconductor element, and a resin seal for covering the semiconductor element. An integrated capacitor is mounted on the heat diffusion member in an opposed relationship to the semiconductor element and electrically connected to the semiconductor element. The integrated capacitor and the semiconductor element are electrically connected over a distance as shortest as possible. The heat diffusion member includes a first conductive layer and a second conductive layer isolated from each other by an insulating layer, some terminals of the integrated capacitor are connected to the corresponding terminals of the substrate through the first conductive layer, and the other terminals of the integrated capacitor are connected to the corresponding terminals of the substrate through the second conductive layer. Thus, an increase of inductance due to additional capacitors can be restricted.

### CROSS-REFERENCE TO RELATED APPLICATION

This application is a continuation of PCT/JP2004/017089, filed on Nov. 17, 2004, the contents being incorporated therein by reference.

### TECHNICAL FIELD

This invention relates to a semiconductor device having a capacitor for stabilizing a power supply and heat diffusion member.

### BACKGROUND ART

A semiconductor device with a semiconductor element mounted on a substrate and sealed with resin is referred to as, for example a BGA or PBGA. Further, a semiconductor device has been proposed in which the semiconductor element is covered by a heat diffusion member (radiation plate) and heat generated by the semiconductor element is discharged out of the semiconductor device through a heat diffusion member (for example, Japanese Unexamined Patent Publication No. 2000-77575 and Japanese Registered Utility Model Publication No. 3074779).

Further, the semiconductor device includes a plurality of capacitors to stabilize the source potential. In the prior art, the plurality of the capacitors are arranged on the front or back surfaces of a substrate separately from each other. This lengthens the distance between the semiconductor element and the capacitors and poses the problem of increased inductance. However, with the recent trend toward a higher and higher operational speed of a semiconductor device, the inductance in the power line and ground line of a semiconductor device is a problem.

### DISCLOSURE OF THE INVENTION

The object of this invention is to provide a semiconductor device in which a capacitor is added for power supply stabilization and an increase in inductance due to the addition of a capacitor can be suppressed.

The semiconductor device according to this invention comprises a substrate, a semiconductor element mounted on the substrate, a heat diffusion member mounted on the substrate while covering the semiconductor element, an integrated capacitor mounted on the heat diffusion member in an opposed relationship to the semiconductor element and electrically connected to the semiconductor element, and a resin seal covering the semiconductor element.

In this configuration, a plurality of capacitors are mounted on a single substrate collectively as an integrated capacitor, which is mounted on the heat diffusion member in an opposed relationship to the semiconductor element. The integrated capacitor is electrically connected to the semiconductor element. Thus, the integrated capacitor and semiconductor element are electrically connected in a shortest distance as possible. Further, since the integrated capacitor is electrically connected to the package substrate with a heat diffusion member as a conduction path, the effect of the inductance, which otherwise might be increased by mounting an integrated capacitor is reduced. In view of the fact that the plurality of the capacitors make up the integrated capacitor, the power supply is also stabilized very effectively. Fabrication costs are decreased due to the fact that only one integrated capacitor is mounted on the heat diffusion member.

### BRIEF DESCRIPTION OF THE DRAWINGS

FIG. 1 is a sectional view showing a semiconductor device according to an embodiment of the invention.

FIG. 2 is a plan view of the integrated capacitor shown in FIG. 1.

FIG. 3 is a plan view showing a first metal plate forming a first conductive layer of the heat diffusion member shown in FIG. 1.

FIG. 4 is a sectional view of the first metal plate taken in line IV-IV in FIG. 3.

FIG. 5 is a plan view showing a second metal plate forming a second conductive layer of the heat diffusion member shown in FIG. 1.

FIG. 6 is a sectional view of the second metal plate taken in line VI-VI in FIG. 5.

FIG. 7 is a bottom view of a metal plate forming the first conductive layer of FIG. 3 having attached an insulating tape thereon.

FIG. 8 is a sectional view of the first metal plate taken in line VIII-VIII in FIG. 7.

FIG. 9 is a bottom view of the first and second metal plates bonded by an insulating adhesive tape.

FIG. 10 is a sectional view of the first and second metal plates taken in line X-X in FIG. 9.

FIG. 11 is a bottom view of the first and second metal plates with the integrated capacitor mounted thereon.

FIG. 12 is a sectional view of the first and second metal plates taken in line XII-XII in FIG. 11.

FIG. 13 is a sectional view of the first and second metal plates taken in line XIII-XIII in FIG. 11.

FIG. 14 is a sectional view of a substrate having a semiconductor element mounted thereon in the fabrication process of the semiconductor device shown in FIG. 1.

FIG. 15 is a sectional view of the heat diffusion member having the integrated capacitor mounted thereon in the fabrication process of the semiconductor device shown in FIG. 1.

FIG. 16 is a sectional view of a semiconductor device according to another embodiment of the invention.

### BEST MODE FOR CARRYING OUT THE INVENTION

An embodiment of the invention is explained below with reference to the drawings.

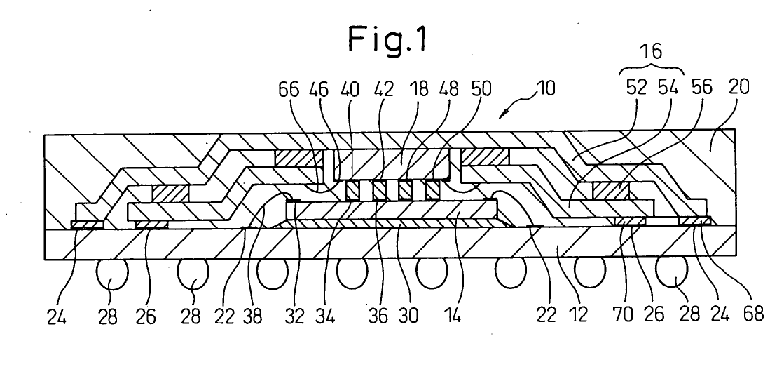

FIG. 1 is a sectional view showing a semiconductor device according to this invention. The semiconductor device 10 includes a substrate 12, a semiconductor element (semiconductor chip) 14 mounted on the substrate 12, a heat diffusion member 16 mounted on the substrate, covering the semiconductor element 14, an integrated capacitor 18 mounted on the heat diffusion member 16 in an opposed relationship to the semiconductor element 14 and electrically connected to the semiconductor element 14, and a resin seal 20 covering the semiconductor element 14. The resin seal 20 covers the heat diffusion member 16 partially. The central portion of the heat diffusion member 16 located above the semiconductor element 14 is exposed out of the resin seal 20, and the peripheral portion of the heat diffusion member 16 is located inside the resin seal 20.

The substrate 12 is a multilayer circuit board and has a circuit pattern formed by a conductor (not shown). The substrate 12 has, on the front surface thereof, signal terminals 22, ground terminals 24 and potential terminals 26 at a predetermined potential level (source potential), and has external terminals 28, such as solder balls on the back surface thereof.

The semiconductor element 14 is fixed to the substrate 12 by a die bonding material 20. The semiconductor element 14 includes a plurality of signal terminals 32 arranged on the peripheral portion of the semiconductor element 14 and a group of ground terminals 34 and potential terminals 36 arranged at the central portion of the semiconductor element 14. The signal terminals 32 of the semiconductor element 14 are connected to the signal terminals 22 of the substrate 12 by wires (bonding wires) 38. The semiconductor element 14 may include ground terminals and potential terminals with signal terminals 32 also on the peripheral portion thereof. The ground terminals and potential terminals of this semiconductor element 14 are connected to the ground terminals and potential terminals (not shown) of the substrate 12 by wires.

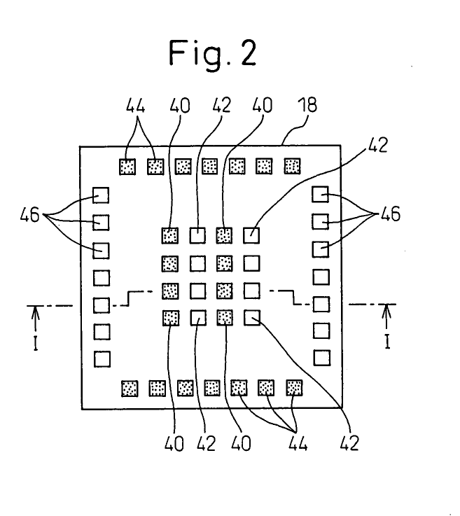

FIG. 2 is a plan view of the integrated capacitor 18 shown in FIG. 1. The integrated capacitor 18 and related wires are shown in the sectional view (corresponding to the sectional view of FIG. 13) of FIG. 1 taken in line I-I in FIG. 2. The integrated capacitor 18 includes a plurality of capacitors integrated on a silicon substrate. The capacitor functions, for example, as a bypass capacitor. A plurality of ground terminals and a plurality of potential terminals are connected to a plurality of the capacitors, respectively, and arranged on the front surface of the integrated capacitor 18. In FIG. 2, the ground terminals are shown in black, and the potential terminals are shown in white.

A plurality of first ground terminals 40 and a plurality of first potential terminals 42 are arranged at the central portion of the integrated capacitor 18, and a plurality of second ground terminals 44 and a plurality of second potential terminals 46 are arranged on the peripheral portion of the integrated capacitor 18. The integrated capacitor 18 includes, for example, 10 to 20 capacitors. In the embodiment shown here, the integrated capacitor 18 includes eight capacitors. Each capacitor has two electrodes, one of which is connected to one of the first ground terminals 40 and two of the second ground terminals 44 internally in the integrated capacitor 18 (not shown), while the other electrode of each capacitor is connected to one of the first potential terminals 42 and two of the second potential terminals 46 internally in the integrated capacitor 18 (not shown), respectively.

The first ground terminals 40 and the first potential terminals 42 are connected to the ground terminals 34 and the potential terminals 36 of the semiconductor element 14 by conductive connecting members 48, 50, respectively. The conductive connecting members 48, 50 may be formed of for example, a stud bump, a wire or a conductive paste or any combination thereof. The second ground terminals 44 and the second potential terminals 46 are connected to the ground terminals 24 and the potential terminals 26 of the substrate 12 through the heat diffusion member 16.

The heat diffusion member 16 is configured of a first metal plate 52 of copper or the like and comprising a first conductive layer and a second metal plate 54 forming a second conductive layer. The first and second metal plates 52, 54 are bonded to each other and electrically isolated from each other by an insulating adhesive tape (two-side tape) 56 of polyimide or epoxy resin. The first and second metal plates 52, 54 are both formed in such a shape as to cover the integrated capacitor 18. The first metal plate 52 is arranged farther (outward) than the second metal plate 54 from the semiconductor element 14.

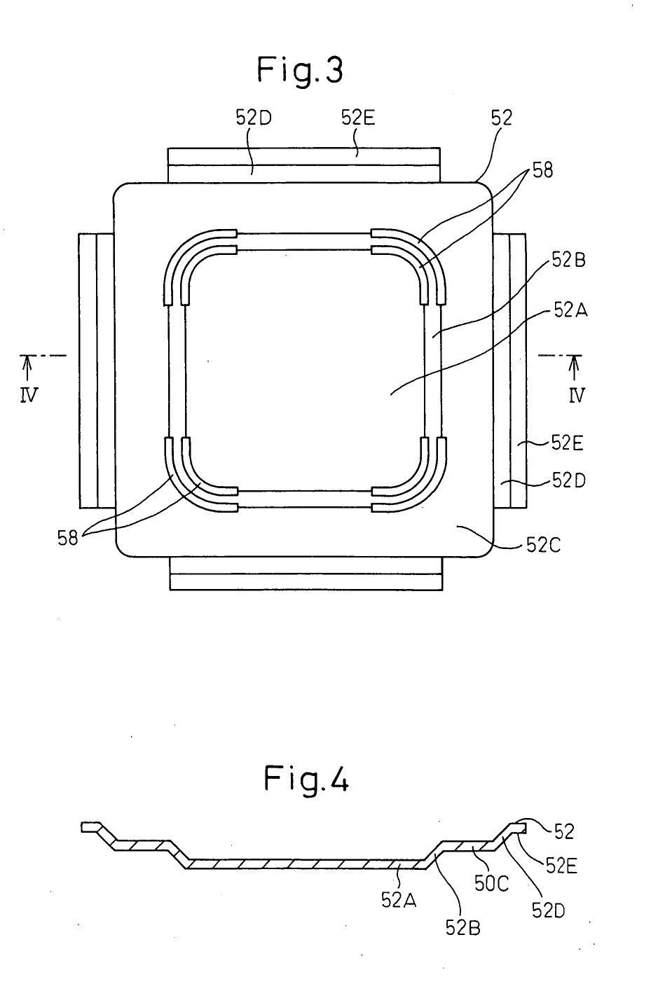

FIGS. 3 to 13 show the first metal plate 52 and the second metal plate 54 of the heat diffusion member 16. FIGS. 3 and 4 show the first metal plate 52 of the heat diffusion member 16. The first metal plate 52 includes a substantially flat central portion 52A, a substantially flat annular portion 52C connected through a stepped portion 52B to the outside of the central portion 52A and an expanded portion 52E connected through the stepped portion 52D to each side of the annular portion 52C. The first metal plate 52 has slots 58 at four corners of the stepped portion 52B.

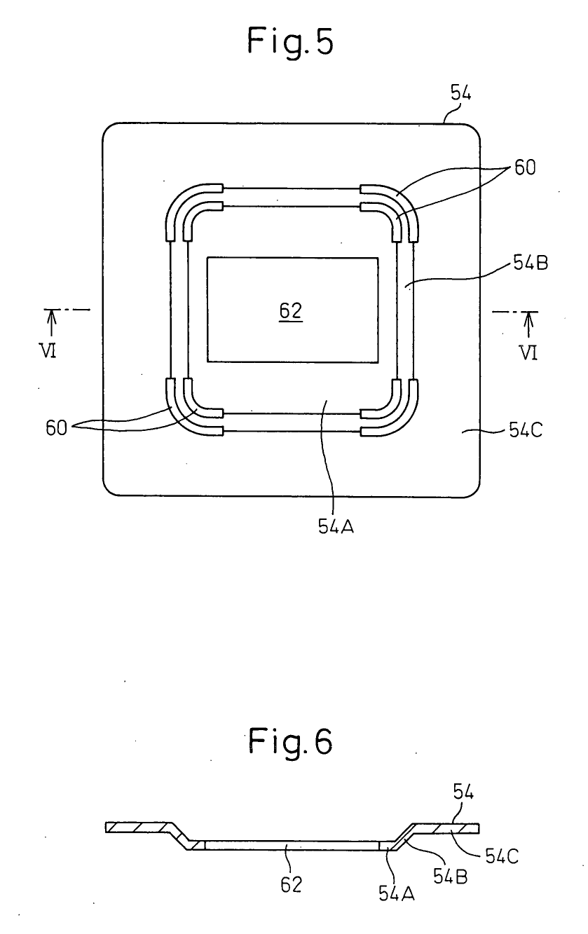

FIGS. 5 and 6 show the second metal plate 54 of the heat diffusion member 16. The second metal plate 54 includes a substantially flat central portion 54A and a substantially flat annular potion 54C connected through the stepped portion 54B to the outside of the central portion 54A. The second metal plate 54 has slots 60 at the four corners of the stepped portion 52B. Further, the second metal plate 54 has a rectangular opening 62 in the central portion 54A.

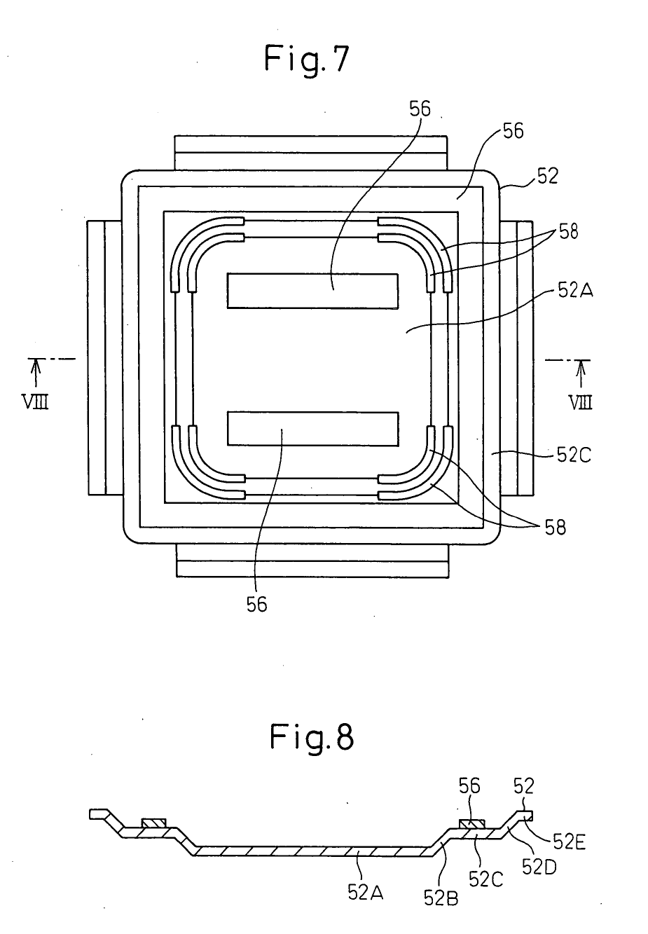

FIGS. 7 and 8 show the first metal plate 52 having an insulating adhesive tapes 56 attached thereon. FIG. 7 shows the inner surface of the first metal plate 52. The insulating adhesive tape 56 in the shape of a rectangular ring is attached to the annular portion 52C of the first metal plate 52, and a pair of band-shaped insulating adhesive tapes 56 are attached to the central portion 52A of the first metal plate 52.

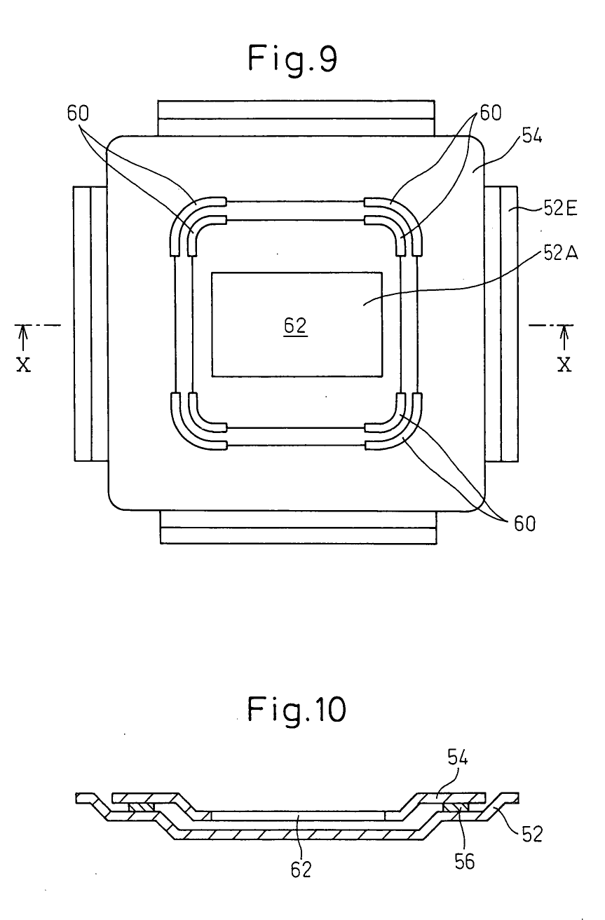

FIGS. 9 and 10 show the first and second metal plats 52, 54 bonded by insulating adhesive tape 56. The second metal plate 54 is arranged on the first metal plate 52 shown in FIGS. 7, 8, and pressure is applied. Then, the first and second metal plates 52, 54 are bonded to each other by the insulating adhesive tape 56. FIG. 9 is a diagram showing the first and second metal plates 52, 54 thus bonded, as viewed from inside the second metal plate 54. A pair of the band-shaped insulating adhesive tape 56 shown in FIG. 7 are located on both sides of the opening 62 of the second metal plate 54 when the first and second metal plates 52, 54 are bonded to each other.

The slots 58 of the first metal plate 52 and the slots 60 of the second metal plate 54 are arranged to communicate with each other. When the resin seal 20 shown in FIG. 1 is formed of a resin seal, melted resin smoothly flows into the heat diffusion member 16 from outside the heat diffusion member 16, thereby improving the resin filling ability.

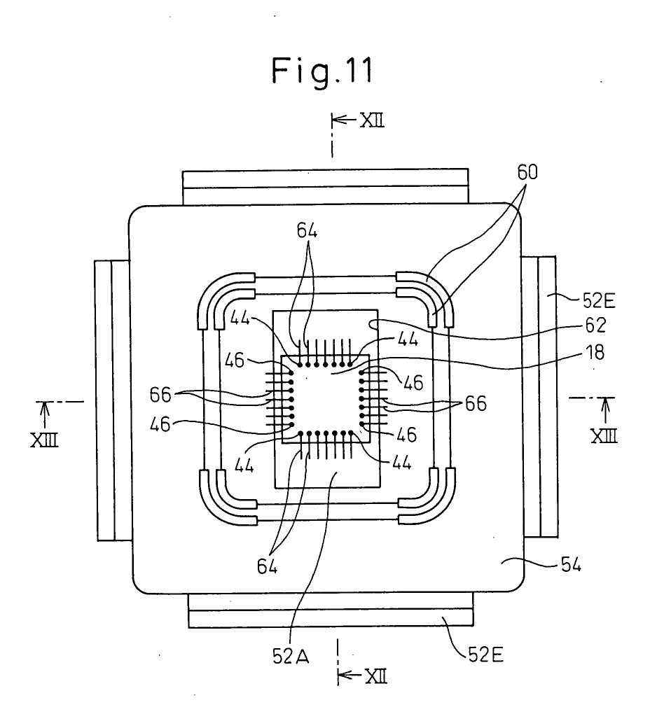

FIGS. 11 to 13 show the first and second metal plates 52, 54 with the integrated capacitor 18 mounted thereon. FIG. 11 is a diagram showing the first and the second metal plates 52, 54 bonded to each other, as viewed from the inside of the second metal plate 54. Referring to FIG. 1 at the same time, the integrated capacitor 18 is fixed to the central portion 52A of the first metal plate 52 by a conductive connecting member, such as conductive paste through the opening 62 of the second metal plate 54.

The integrated capacitor 18, as shown in FIG. 2, includes a plurality of first ground terminals 40 and a plurality of first potential terminals 42 located at the central portion and a plurality of second ground terminals 44 and a plurality of second potential terminals 46 located on the peripheral portion. In FIGS. 11 to 13, the ground terminals and the potential terminals are located at the central portion (not shown). On the other hand, the plurality of the second ground terminals 44 and the plurality of the second potential terminals 46 located on the peripheral portion, are arranged in a similar manner to FIG. 2.

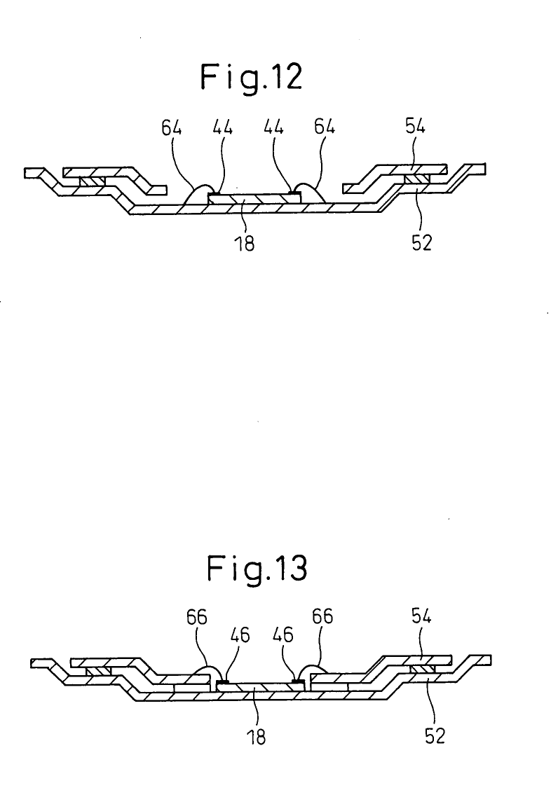

As shown in FIGS. 11, 12, the second ground terminals 44 of the integrated capacitor 18 are connected to the first metal plate 52 of the heat diffusion member 16 by wires (bonding wires) 64. As shown in FIGS. 11, 13, the second potential terminals 46 of the integrated capacitor 18 are connected to the second metal plate 54 of the heat diffusion member 16 by wires (bonding wire) 66. FIG. 1 shows only wires 66 for connecting the potential terminals 46 and the second metal plate 54.

In FIG. 1, the first metal plate 52 of the heat diffusion member 16 is connected to the ground terminal 24 of the substrate 12 by conductive connecting member 68, and the second metal plate 54 of the heat diffusion member 16 is connected to the potential terminal 26 of the substrate 12 by the conductive connecting member 70. The second ground terminals 44 and the second potential terminals 46 of the integrated capacitor 18, are connected to the ground terminals 24 and the potential terminals 26, respectively, of the substrate 12 through the wires 64, 66 and the first and second metal plates 52, 54. The wires 64, 66 are comparatively short, and therefore small in inductance. The first and second metal plates 52, 54 have a large area that voltage drops across them are small.

In the configuration described above, a plurality of capacitors are collectively arranged as an integrated capacitor 18 on a single substrate, and the integrated capacitor 18 is mounted on the heat diffusion member 16 in an opposed relationship to the semiconductor element 14. The integrated capacitor 18 and the semiconductor element 14 are connected electrically to each other at a distance as shortest as possible, and therefore, the inductance of each capacitor can be reduced. Also, in view of the fact that the plurality of the capacitors are integrally formed as an integrated capacitor 18, only a single integrated capacitor 18 is required to be mounted on the heat diffusion member 16, thereby contributing to a lower fabrication costs.

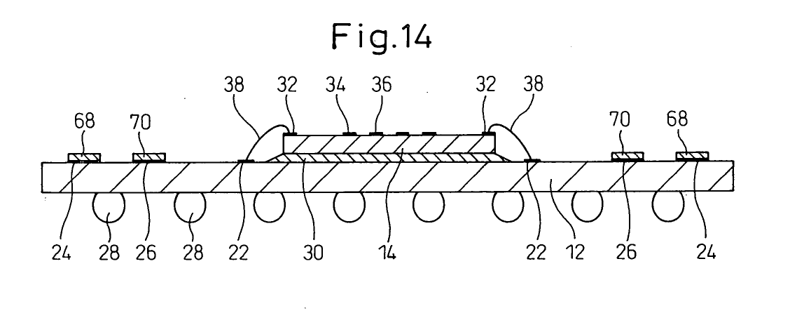

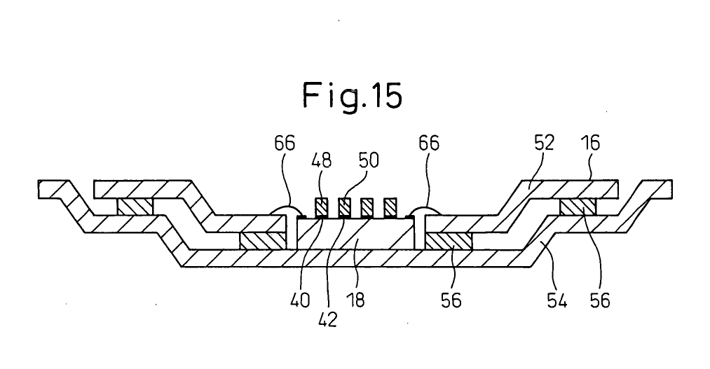

FIG. 14 is a sectional view of the substrate 12 having the semiconductor element 14 mounted thereon in the fabrication process of the semiconductor device 10 shown in FIG. 1. FIG. 15 is a sectional view of the heat diffusion member 16 having the integrated capacitor 18 mounted thereon in the fabrication process of the semiconductor device 10 shown in FIG. 1. The semiconductor device 10 shown in FIG. 1 is fabricated by the fabrication method shown in, for example, FIGS. 14 and 15.

In FIG. 14, the substrate 12 having the semiconductor element 14 mounted thereon is prepared. The substrate 12 is formed with signal terminals 22, ground terminals 24, potential terminals 26 and external terminals 28. The semiconductor element 14 is fixed to the substrate 12 by a die bonding material 30. The semiconductor element 14 is formed with signal terminals 32, ground terminals 34 and potential terminals 36. The signal terminals 32 of the semiconductor element 14 are connected to the signal terminals 22 of the substrate 12 by wires 38. The ground terminals 24 and potential terminals 26 are coated or formed with conductive connecting members 68, 79, such as a conductive paste.

In FIG. 15, the heat diffusion member 16 having the integrated capacitor 18 mounted thereon is prepared. The heat diffusion member 16 includes a first metal plate 52 constituting a first conductive layer and a second metal plate 54 constituting a second conductive layer isolated from each other by insulating adhesive tape 56 constituting an insulating layer. The heat diffusion member 16 having the integrated capacitor 18 mounted thereon is fabricated, for example, in the manner explained above with reference to FIGS. 3 to 13. The second metal plate 54 has an opening 62 at the central portion thereof, and the integrated capacitor 18 is fixed to the first metal plate 52 by the conductive connecting member such as a conductive paste through the opening 62.

The second ground terminals 44 of the integrated capacitor 18 are connected to the first metal plate 52 of the heat diffusion member 16 by wires 64, and the second potential terminals 46 connected to the second metal plate 54 of the heat diffusion member 16 by wires 66. The first ground terminals 40 and the first potential terminals 42 are coated or formed with conductive connecting members 48, 50.

In the inverted state of the heat diffusion member 16 of FIG. 15, the heat diffusion member 16 is pressed against the substrate 12 shown in FIG. 14. The first ground terminals 40 and the first potential terminals 42 of the integrated capacitor 18 are pressed against the ground terminals 34 and the potential terminals 36 of the semiconductor element 14 and fixed by the conductive connecting members 48, 50. The first and second metal plates 52, 54 are pressed against the ground terminals 24 and the potential terminals 26 of the substrate 12 and fixed by the conductive connecting members 68, 70. After that, the semiconductor device 10 shown in FIG. 1 is obtained by resin molding using a resin seal 20. The external terminals 28 may be arranged on the substrate 12 after resin molding.

According to this embodiment, the conductive connecting members 48, 50 may be arranged on the semiconductor element 14 instead of on the integrated capacitor 18. In a similar fashion, the conductive connecting members 68, 70 may be arranged on the first and second metal plates 52, 54 of the heat diffusion member 16 instead of on the substrate 12. Further, the conductive connecting members 48, 50, 68, 70 may be formed of stud bumps or ball bonding wires, such as gold wires in place of the conductive paste. As another alternative, these conductive connecting members can be a combination of connecting members, such as conductive paste or stud bumps.

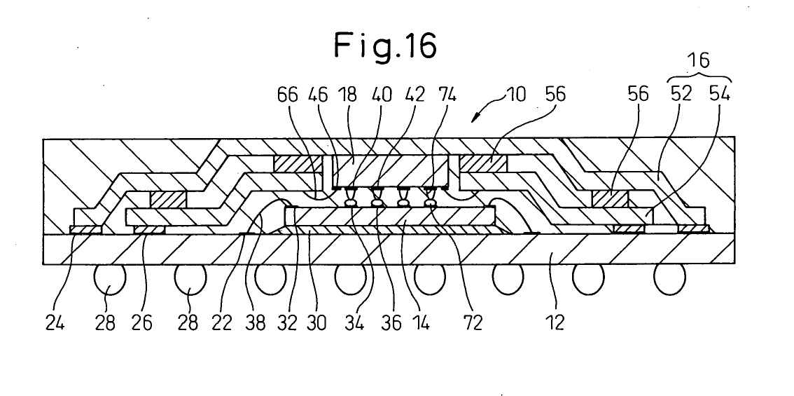

FIG. 16 is a sectional view of a semiconductor device according to another embodiment of the invention. As in the embodiment shown in FIG. 1, the semiconductor device 10 includes a substrate 12, a semiconductor element (semiconductor chip) 14 mounted on the substrate 12, a heat diffusion member 16 mounted on the substrate 12 in such a manner as to cover the semiconductor element 14, an integrated capacitor 18 mounted on the heat diffusion member 16 in an opposed relationship and connected electrically to the semiconductor element 14, and a resin seal 20 for covering the semiconductor element 14. The resin seal 20 covers the heat diffusion member 16 partially.

The substrate 12 is formed of a multilayer circuit board, and includes signal terminals 22, ground terminals 24, potential terminals 26 at a predetermined potential (source potential) and external terminals 28. The semiconductor element 14 is fixed to the substrate 12 by a die bonding material 30. The semiconductor element 14 includes signal terminals 32 arranged on the peripheral portion thereof, and a group of ground terminals 34 and potential terminals 36 arranged at the central portion thereof. The signal terminals 32 of the semiconductor element 14 are connected to the signal terminals 22 of the substrate 12 by wires 38. The integrated capacitor 18, as shown in FIG. 2, includes a plurality of first ground terminals 40, a plurality of first potential terminals 42, a plurality of second ground terminals 44 and a plurality of second potential terminals 46.

According to this embodiment, the conductive connecting members for connecting the ground terminals 34 and the potential terminals 36 of the semiconductor element 14 to the first ground terminals 40 and the first potential terminals 42 of the integrated capacitor 18 are configured of bumps 72 arranged on the semiconductor element 14 and loop wires 74 arranged on the integrated capacitor 18.

Another configuration shown in FIG. 16 is similar to that of FIG. 1. Specifically, the second ground terminals 44 and the second potential terminals 46 are connected to the ground terminals 24 and the potential terminals 26 of the substrate 12 through the heat diffusion member 16. The heat diffusion member 16 is configured of a first metal plate 52 and a second metal plate 54 bonded to each other and electrically isolated from each other by an insulating adhesive tape (two-side tape) 56. The heat diffusion member 16 having the integrated capacitor 18 mounted thereon is similar to the one shown in FIGS. 3 to 13. The first metal plate 52 has slots 58, and the second metal plate 54 slots 60 and an opening 62. The integrated capacitor 18 is fixed to the first metal plate 52 by a conductive connecting member such as conductive paste through the opening 62 of the second metal plate 54. The slots 58, 60 of the first and second metal plates 52, 54 are formed in order to allow the smooth flow of melted resin into the heat diffusion member 16 when forming the resin seal 20 thereby improving the resin filling ability.

### INDUSTRIAL APPLICABILITY

As explained above, according to this invention, there is provided a semiconductor device having a low effect of inductance, which otherwise might be increased by adding a capacitor for stabilizing the source potential. Also, a plurality of capacitors are configured as an integrated capacitor, and electrically connected to the package substrate through a heat diffusion member as a conduction path, thereby leading to a highly stable source potential. Also, only one integrated capacitor is required to be mounted on the heat diffusion member in the fabrication process, and therefore, costs can be decreased.

1. A semiconductor device, comprising:
a substrate;
a semiconductor element mounted on the substrate;
a heat diffusion member mounted on the substrate while covering the semiconductor element;
an integrated capacitor mounted on the heat diffusion member in opposed relation to the semiconductor element, and electrically connected to the semiconductor element; and
a resin seal for covering the semiconductor element.

2. The semiconductor device as claimed in claim 1, wherein the integrated capacitor includes a plurality of first ground terminals and a plurality of first potential terminals, the first ground terminals of the integrated capacitor are connected to ground terminals of the semiconductor element, and the first potential terminals of the integrated capacitor are connected to potential terminals of the semiconductor element.

3. The semiconductor device as claimed claim 2, wherein the integrated capacitor further includes a plurality of second ground terminals and a plurality of second potential terminals, and the second ground terminals and the second potential terminals of the integrated capacitor are connected to ground terminals and potential terminals of the substrate through the heat diffusion member.

4. The semiconductor device as claimed in claim 3, wherein the heat diffusion member includes a first conductive layer and a second conductive layer isolated from each other by an insulating layer, the second ground terminals of the integrated capacitor are connected to the ground terminals of the substrate through the first conductive layer of the heat diffusion member, and the second potential terminals of the integrated capacitor are connected to the potential terminals of the substrate through the second conductive layer of the heat diffusion member.

5. The semiconductor device as claimed in claim 4, wherein the integrated capacitor is mounted on the first conductive layer of the heat diffusion member by a conductive connecting member.

6. The semiconductor device as claimed in claim 5, wherein the second ground terminals of the integrated capacitor are connected to the first conductive layer of the heat diffusion member by first wires, and the second potential terminals of the integrated capacitor are connected to the second conductive layer of the heat diffusion member by second wires.

7. The semiconductor device as claimed in claim 6, wherein the conductive connecting member for connecting the potential terminals of the semiconductor element to the first potential terminals of the integrated capacitor and the conductive connecting member for connecting the ground terminals of the semiconductor element to the first ground terminals of the integrated capacitor are formed of wires arranged at the terminals of the integrated capacitor and bumps arranged at the terminals of the semiconductor element.

8. The semiconductor device claimed in claim 4, wherein the first and second conductive layers of the heat diffusion member are each formed of a metal plate, and the insulating layer is formed of an insulating adhesive tape for bonding the two metal plates to each other.

9. The semiconductor device claimed in claim 4, wherein the first and second conductive layers and the insulating layer of the heat diffusion member have slots for filling the resin for resin sealing.

10. The semiconductor device claimed in claim 4, wherein the first conductive layer of the heat diffusion member is located farther from the semiconductor element than the second conductive layer, the second conductive layer has an opening for positioning the integrated capacitor, and the integrated capacitor is fixed to the first conductive layer through the opening of the second conductive layer.
